(19) United States
(12) Patent Application Publication
(10) Pub. No.: US 2008/0279001 A1
(43) Pub. Date: Nov. 13, 2008

(54) OPERATING METHOD OF NON-VOLATILE MEMORY

(75) Inventors: Saysamone Pittikoun, Taipei City (TW); Houng-Chi Wei, Hsinchu City (TW); Chih-Chen Cho, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 11/927,702

(22) Filed: Oct. 30, 2007

Related U.S. Application Data
(62) Division of application No. 11/162,330, filed on Sep. 7, 2005, now abandoned.

(30) Foreign Application Priority Data
Mar. 4, 2005 (TW) 94106549

(51) Int. Cl. G11C 16/04; G11C 16/06

(52) U.S. Cl. 365/185.05; 365/185.18

(57) ABSTRACT

A non-volatile memory having a plurality of memory units each including a select unit and a memory unit is provided. The select unit is disposed on the substrate. The memory cell is disposed on one sidewall of the select unit and the substrate. The select unit includes a gate disposed on the substrate and a first gate dielectric layer disposed between the gate and the substrate. The memory cell includes a pair of floating gate disposed on the substrate, a control gate disposed on the upper surface of the floating gates, an inter-gate dielectric layer disposed between the floating gate and the control gate, a tunneling dielectric layer disposed between the floating gate and the substrate and a second gate dielectric layer disposed between the bottom of the control gate and the substrate.

### CROSS-REFERENCE TO RELATED APPLICATION

This application is a divisional of an application Ser. No. 11/162,330, filed on Sep. 7, 2005, now pending, which claims the priority benefit of Taiwan application serial no. 94106549, filed on Mar. 4, 2005. The entirety of each of the above-mentioned patent applications is hereby incorporated by reference herein and made a part of this specification.

### BACKGROUND OF THE INVENTION

1. Field of the Invention

The present invention relates to a memory device. More particularly, the present invention relates to a non-volatile memory and manufacturing method and operating method thereof.

2. Description of the Related Art

Among the various types of non-volatile memory products, electrically erasable programmable read only memory (EEPROM) is a memory device that has been widely used inside personal computer systems and electron equipment. Data can be stored, read out or erased from the EEPROM many times and stored data are retained even after power supplying the devices is cut off.

Typically, the floating gates and the control gates of the EEPROM non-volatile memory are fabricated using doped polysilicon. Furthermore, the floating gates and the control gates are isolated from each other by an inter-gate dielectric layer and the floating gates and the substrate are isolated through a tunneling dielectric layer. To write data to or erase data from the memory, a biased voltage is applied to the control gate and the source/drain region so that electric charges are injected into the floating gate or pulled out from the floating gate. To read data from the memory, an operating voltage is applied to the control gate. Because the threshold voltage of the floating gate has been changed through a previous write/erase operation, the difference in the threshold voltage is interpreted as a data value of ‘0’ or ‘1’ in the data read-out.

However, because the floating gate is a layer of continuous semiconductor material (a polysilicon layer), the injected electric charges will distribute evenly within the entire floating gate. Therefore, this type of memory permits the storage of at most a single bit of data in each memory cell and thus cannot be used as a multi-level memory cell device.

Furthermore, to prevent the data judgement errors due to serious over-erasure in the erasing operation, an additional select gate is often disposed on the sidewalls of the control gate and the floating gate above the substrate to form a split-gate structure.

Yet, a device having a split-gate structure needs to have a large surface area for accommodating the select gate. Hence, it is difficult to increase the level of integration of the non-volatile memory.

### SUMMARY OF THE INVENTION

Accordingly, at least one objective of the present invention is to provide a non-volatile memory and manufacturing method and operating method thereof that can increase the level of integration of memory cells and improve device performance.

At least a second objective of the present invention is to provide a non-volatile memory and manufacturing method and operating method thereof that utilizes source-side injection (SSI) to carry out programming operations. Hence, the speed for programming the memory is increased and the performance of the memory is improved.

At least a third objective of the present invention is to provide a non-volatile memory and manufacturing method and operating method thereof that can increase the storage capacity of the memory, simplify the process and reduce the production cost.

To achieve these and other advantages and in accordance with the purpose of the invention, as embodied and broadly described herein, the invention provides a non-volatile memory unit. The non-volatile memory unit includes a select unit, a first insulating layer and a memory cell. The select unit is disposed on the substrate. The memory cell is disposed on the substrate and is adjacent to the select unit through the first insulating layer. The select unit further includes a first gate disposed on the substrate and a first inter-gate dielectric layer disposed between the first gate and the substrate. The memory cell further includes a pair of floating gates disposed on the substrate, a control gate disposed on the upper surface of the floating gates with the bottom of the control gate on the substrate between the floating gates, an inter-gate dielectric layer disposed between the floating gate and the control gate, a tunneling dielectric layer disposed between the floating gates and the substrate and a second gate dielectric layer disposed between the bottom of the control gate and the substrate. The floating gates are doped polysilicon spacers formed in a self-aligned anisotropic etching operation, for example. Moreover, the arc-shaped sidewall of the respective floating gates faces each other.

In the non-volatile memory of the present invention, the plurality of select units and the plurality of memory cells are alternately laid to form memory unit rows. Because there is no gap between each select unit and an adjacent memory cell, overall level of integration of the memory cell array is increased. Furthermore, each memory cell includes two separated conductive spacers each capable of acting as a floating gate so that each memory cell can store up to two bits of data. Consequently, the storage capacity of each memory cell is increased and each memory cell may serve as a multi-level memory device.

The present invention also provides an alternative non-volatile memory. The non-volatile memory includes a plurality of the aforementioned non-volatile memory units, a switching unit, a first doped region and a second doped region. The non-volatile memory units are serially connected through a series of intervening second insulating layers. The switching unit is disposed on the substrate and connected to the outermost memory cell through a third insulating layer. The switching unit includes a second gate disposed on the substrate and a third gate dielectric layer disposed between the second gate and the substrate. The first doped region is disposed in the substrate on the outer side of the outermost select unit. The second doped region is disposed in the substrate on the outer side of the switching unit.

The present invention also provides another non-volatile memory. The non-volatile memory includes a substrate, a plurality of stacked gate structures, a plurality of conductive spacers, an insulating layer, a tunneling dielectric layer, a plurality of second gates, a second gate dielectric layer, an inter-gate dielectric layer, a first doped region and a second doped region. The stacked gate structures are disposed on the substrate. Each stacked gate structure includes a first gate dielectric layer and a first gate sequentially stacked on the substrate and every pair of adjacent stacked gate structures has a gap. The conductive spacers are disposed on the sidewalls of the stacked gate structures. The insulating layer is disposed between the conductive spacers and the stacked gate structures. The tunneling dielectric layer is disposed between the conductive spacers and the substrate. The second gate completely fills the gap between two adjacent stacked gate structures and covers the upper surface of the conductive spacers. The second gates and the stacked gate structures are connected to form a memory cell row. The second gate dielectric layer is disposed between the second gates and the substrate. The inter-gate dielectric layer is disposed between the second gates and the conductive spacers. The first doped region and the second doped regions are disposed in the substrate on the respective sides of the memory cell row.

In the non-volatile memory of the present invention, the plurality of second gates and the stacked gate structures are alternately laid to form memory unit rows. Because there is no gap between each second gate and an adjacent stacked gate structure, the level of integration of the memory cell array is increased. Furthermore, each memory cell includes two separated conductive spacers each capable of acting as a floating gate so that each memory cell can store up to two bits of data. Consequently, the storage capacity of each memory cell is increased and each memory cell may serve as a multi-level memory device.

The present invention also provides a method of operating a non-volatile memory such as a memory unit array. The memory unit array includes a plurality of memory units each having a select unit and a memory cell. The select unit and the memory cell of the memory cell units are alternately laid without any gap between to form a serially connected memory unit row. Furthermore, each memory cell includes at least a pair of separated floating gates. A plurality of switching units is disposed to connect with the outermost memory cell of the respective memory unit rows. A plurality of drain regions is disposed in the substrate on the outer side of the respective switching units of the memory unit rows. A plurality of source regions is disposed in the substrate on the outer side of the respective outermost select units of the memory unit rows. A plurality of first word lines is aligned in parallel to the column direction to connect with the control gate of the memory cells in the same column. A plurality of second word lines is aligned in parallel to the column direction to connect with the gate of the select units in the same column. A plurality of third word lines is disposed to connect with the gate of the switching units in the same column. A plurality of bit lines is aligned in parallel to the row direction to connect with the drain regions in various memory unit rows. A plurality of source lines is disposed to connect with the source regions of various memory unit rows. To program a first bit of data into a selected memory cell within the non-volatile memory, a 0V is applied to the selected bit line, a first voltage is applied to the selected third word line, a second voltage is applied to the non-selected first word line, the second word line and the third word line and a third voltage is applied to the selected source line. Hence, source-side injection (SSI) is triggered so that a first bit is transferred into the floating gate close to the drain region of the selected memory cell. To program a second bit of data into a selected memory cell within the non-volatile memory, a 0V is applied to the selected bit line, the first voltage is applied to the first word line that couples with the selected memory cell, the second voltage is applied to the non-selected first word line, the second word line and the third word line and the third voltage is applied to the selected source line. Hence, source-side injection (SSI) is triggered so that a second bit is transferred into the floating gate close to the source region of the selected memory cell.

To erase data from the memory in the aforementioned method of operating the non-volatile memory, the selected bit line and the source liner are set to a floating state, a fourth voltage is applied to the selected third word line and the substrate and a 0V is applied to the non-selected first word line, the second word line and the third word line. Hence, F-N tunneling is triggered to erase the data.

To read a first bit of data from the memory in the aforementioned method of operating the non-volatile memory, a 0V is applied to the selected bit line, a fifth voltage is applied to the first word line that couple with the selected memory cell and the source line and a sixth voltage is applied to the non-selected first word line, the second word line and the third word line. Hence, the first bit of data is read from the floating gate close to the drain region of the selected memory cell. To read a second bit of data from the memory, a 0V is applied to the selected source line, the fifth voltage is applied to the first word line that couple with the selected memory cell and the bit line and the sixth voltage is applied to the non-selected first word line, the second word line and the third word line. Hence, the second bit of data is read from the floating gate close to the source region of the selected memory cell.

The method of operating the non-volatile memory according to the present invention utilizes source-side injection for programming data into the memory and F-N tunneling effect to erase data from the memory cells. Furthermore, a bi-directional read-out scheme is used to read the left and the right data bit from a selected memory cell. Because the electron injection efficiency is raised in the present invention, the memory cell current can be reduced and the operating speed can be increased. As a result, current consumption is minimized and power loss from the entire chip is reduced.

The present invention also provides a method of fabricating a non-volatile memory including the following steps. Firs, a substrate is provided and then a plurality of stacked gate structures is formed on the substrate. Each stacked gate structure includes a first gate dielectric layer, a first gate and a cap layer sequentially formed on the substrate. There is a gap between every pair of adjacent stacked gate structures. Thereafter, an insulating layer is formed on the sidewalls of the stacked gate structures within the gap. A tunneling dielectric layer is formed over the substrate. After that, conductive spacers are formed over the insulating layer on the sidewalls of the stacked gate structures. Then, an inter-gate dielectric layer is formed on the substrate to cover at least the conductive spacers and the tunneling dielectric layer. The inter-gate dielectric layer and the tunneling dielectric layer between two adjacent conductive spacers are removed to expose a portion of the substrate. Thereafter, a second gate dielectric layer is formed over the exposed substrate in the gaps. A first conductive layer is formed over the substrate to fill at least the gap between two adjacent stacked gate structures. Then, a portion of the first conductive layer is removed until the cap layer is exposed to form a plurality of second gates between two adjacent stacked gate structures. The second gates together with the stacked gate structures form a memory cell row. After that, a source region and a drain region are formed in the substrate on the respective sides of the memory cell row.

In the method of fabricating the non-volatile memory according to the present invention, the conductive spacers (floating gates) and the second gates (the control gates) are formed in the space between neighboring stacked gate structures to produce memory cells without performing photolithographic and etching processes. Hence, the process of fabricating non-volatile memory is simplified and overall production cost is reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view showing the layout of a non-volatile memory according to the present invention.

FIG. 1B is a schematic cross-sectional view along line A-A′ of FIG. 1A.

FIG. 1C is a schematic cross-sectional view showing the structures of a memory cell and a switching unit according to the present invention.

FIG. 2A is a schematic cross-sectional view for showing the programming of a non-volatile memory according to one embodiment of the present invention.

FIG. 2B is a schematic cross-sectional view for showing the programming of data into a non-volatile memory according to another embodiment of the present invention.

FIG. 3 is a schematic cross-sectional view for showing the erasing of data from a non-volatile memory according to one embodiment of the present invention.

FIG. 4A is a schematic cross-sectional view for showing the reading of data from a non-volatile memory according to one embodiment of the present invention.

FIG. 4B is a schematic cross-sectional view for showing the reading of data from a non-volatile memory according to another embodiment of the present invention.

FIGS. 5A through 5E are schematic cross-sectional views along line A-A′ of FIG. 1A showing the steps for fabricating a non-volatile memory according to the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

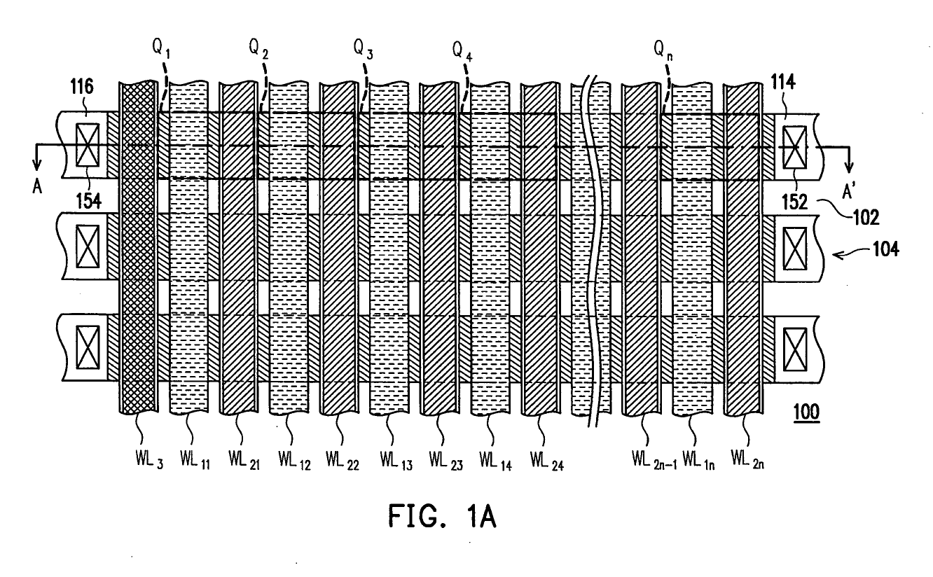

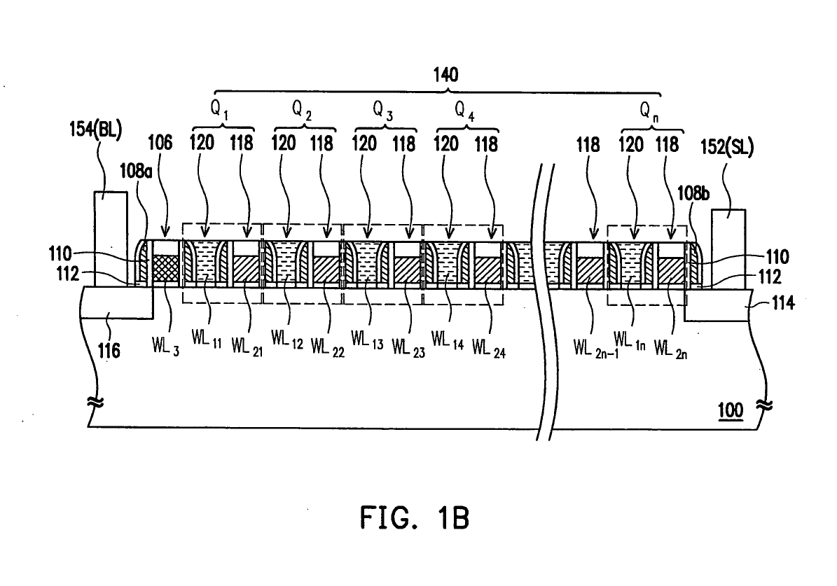

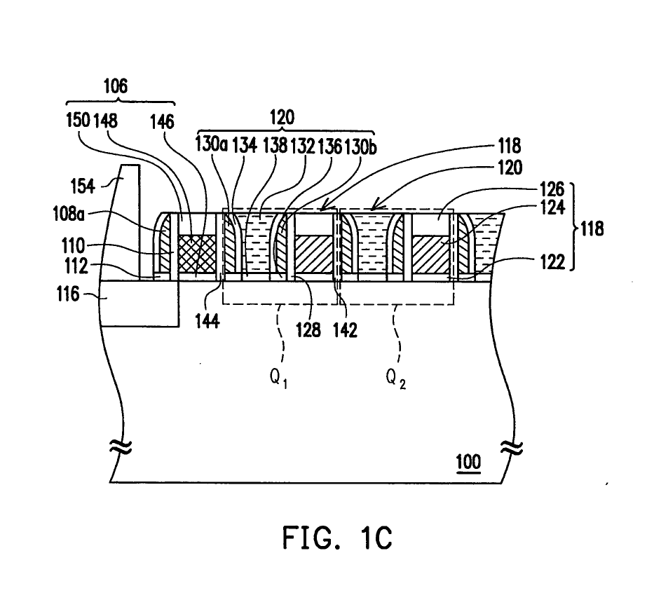

FIG. 1A is a top view showing the layout of a non-volatile memory according to the present invention. FIG. 1B is a schematic cross-sectional view along line A-A′ of FIG. 1A. FIG. 1C is a schematic cross-sectional view showing the structures of a memory cell and a switching unit according to the present invention.

As shown in FIGS. 1A, 1B and 1C, the non-volatile memory of the present invention includes at least a substrate 100, a device isolation structure 102, an active region 104, a plurality of memory units Q1˜Qn, a switching unit 106, a plurality of conductive spacers 108a, 108b, an insulating layer 110, a gate dielectric layer 112, a source region 114 and a drain region 116.

The substrate 100 is a silicon substrate, for example. The substrate can be a P-type substrate or an N-type substrate. The device isolation structure 102 is disposed in the substrate 100 for defining out the active region 104.

The memory units Q1˜Qn are disposed on the substrate 100. Each memory unit Q1˜Qn includes a select unit 118 and a memory cell 120.

The select units 118 are disposed on the substrate 100. Each select unit 118 includes a gate dielectric layer 122, a gate 124 and a cap layer 126, for example. The gate 124 is disposed on the substrate 100 and the gate dielectric layer 122 is disposed between the gate 124 and the substrate 100. The cap layer 126 is disposed on the gate 124. The gate dielectric layer 122 is fabricated from silicon oxide, the gate 124 is fabricated from doped polysilicon and the cap layer 126 is fabricated from silicon oxide, for example.

The memory cells 120 are disposed on the substrate 100 adjacent to the respective select units 118 through an insulating layers 128. Each memory cell 120 includes a pair of floating gates 130a, 130b, a control gate 132, an inter-gate dielectric layer 134, a tunneling dielectric layer 136 and a gate dielectric layer 138, for example. The floating gates 130a and 130b are disposed on the substrate 100. The floating gate 130a connects with the select unit 118 through the insulating layer 128. In the present embodiment, the floating gates 130a and 130b are spacers formed in a self-aligned anisotropic etching process such that the arc-shaped sidewall of the floating gates 130a and 130b face each other. The control gate 132 is disposed over the upper surface of the floating gates 130a and 130b. Furthermore, the bottom of the control gate 132 is disposed over the substrate 100 between the floating gates 130a and 130b. The inter-gate dielectric layer 134 is disposed between the floating gate 130a and the control gate 132 and between the floating gate 130b and the control gate 132. The tunneling dielectric layer 136 is disposed between the floating gate 130a and the substrate 100 and between the floating gate 130b and the substrate 100. The gate dielectric layer 138 is disposed between the bottom of the control gate 132 and the substrate 100. The floating gates 130a, 130b and the control gate 132 are fabricated from doped polysilicon, and the inter-gate dielectric layer 134 is fabricated from silicon oxide or an oxide/nitride/oxide composite dielectric layer, for example. The tunneling dielectric layer 136 and the gate dielectric layer 138 are fabricated from silicon oxide, for example.

The memory units Q1˜Qn are serially connected together on the active region 104 to form a memory unit row 140. Furthermore, the select units 118 and the memory cells 120 are alternately aligned so that no gap exists between them. The memory units Q1˜Qn within the memory unit row 140 are isolated from each other through an insulating layer 142. The memory cell rows 140 are isolated from each other through the device isolation structure 102.

The switching unit 106 is disposed on the substrate 100 and is connected to the outermost memory cell 120 in the memory unit row 140 through an insulating layer 144. The switching unit 106 includes a gate dielectric layer 146, a gate 148 and a cap layer 150, for example. The gate 148 is disposed on the substrate 100. The gate dielectric layer 146 is disposed between the gate 148 and the substrate 100. The cap layer 150 is disposed on the gate 148. The gate dielectric layer 146 is fabricated using silicon oxide; the gate 148 is fabricated using doped polysilicon; and, the cap layer 126 is fabricated using silicon oxide, for example.

Conductive spacers 108a and 108b are disposed on the outermost sidewall of the select unit 118 and the outermost sidewall of the switching unit 106 respectively. The conductive spacers 108a and 108b are fabricated using doped polysilicon, for example. The insulating layer 110 is disposed between the conductive spacer 108a and the switching unit 106 and between the conductive layer 108b and the outermost select unit 118. The insulating layer 110 is fabricated using silicon oxide or silicon nitride, for example. The gate dielectric layer 112 is disposed between the conductive spacer 108a and the substrate 100 and between the conductive spacer 108b and the substrate 100. The gate dielectric layer 112 is fabricated using silicon oxide, for example.

The drain region 116 is disposed in the substrate 100 on the outer side of the switching unit 106. The source region 114 is disposed in the substrate on the outer side of the outermost select unit 118.

The source region 114 of each memory unit row 140 is electrically connected to a source line (SL) 152. Similarly, the drain region 116 of each memory unit row 140 is electrically connected to a bit line (BL) 154. The control gate 132 of the memory cells 120 in the same column are electrically connected to the respective first word lines WL11˜W1n. The first word lines WL11˜W1n are aligned in parallel to the column direction. The gate 124 of the select units 118 in the same column are electrically connected to the respective second word lines WL21˜W2n. The second word lines WL21˜W2n are aligned in parallel to the column direction. The gate 148 of the switching units 106 in the same column are electrically connected to a third word line WL3. The third word line WL3 is aligned in the column direction.

The non-volatile memory in the present invention has a plurality of memory unit rows 140 each including of a plurality of alternately laid select units 118 and memory cells 120. Since there is no gap between the select unit 118 and the memory cell 120 and there is no gap between the switching unit 106 and the memory cell 120, the level of integration in the memory cell array can be increased. Furthermore, each memory cell 120 includes two separated floating gates 130a and 130b. Hence, two bits of data can be stored in a single memory cell so that the storage capacity of the non-volatile memory is increased and each memory cell can serve as a multi-level memory device.

In addition, the number of serially connected memory units in the present invention can be increased or decreased to meet the actual requirement. For example, a total of between 32 to 64 of memory units can be serially connected together to form a memory unit row 140.

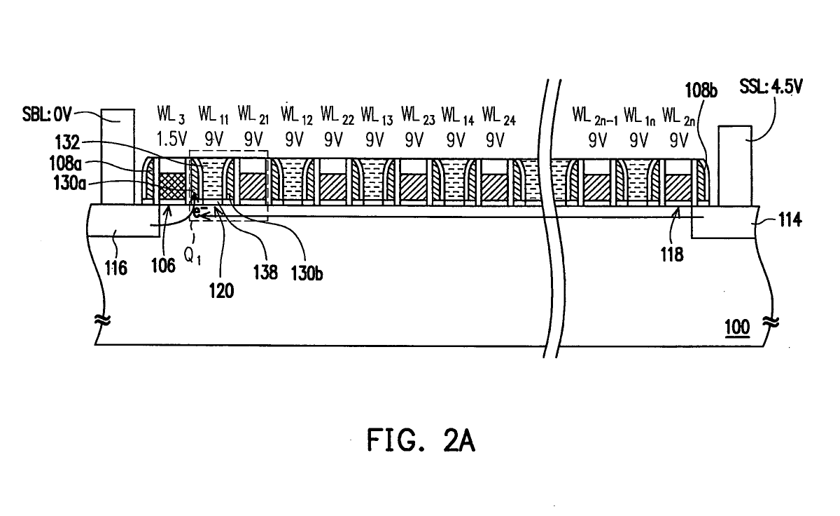

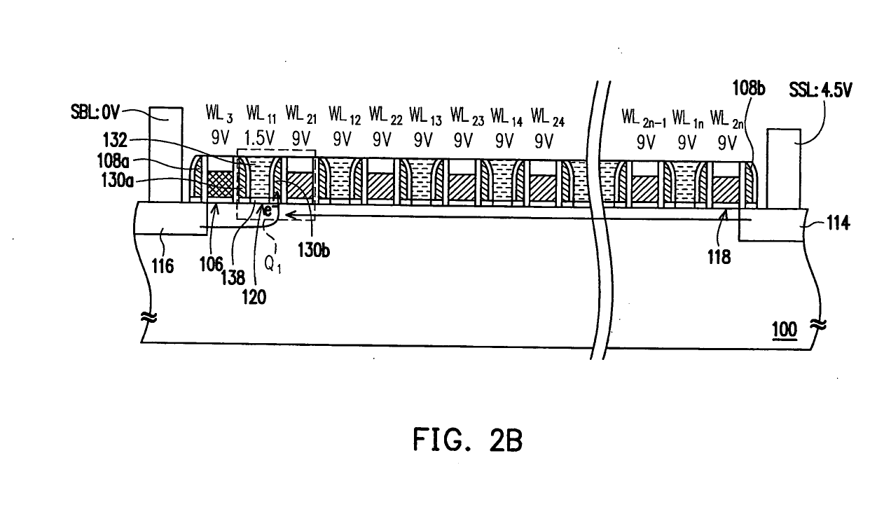

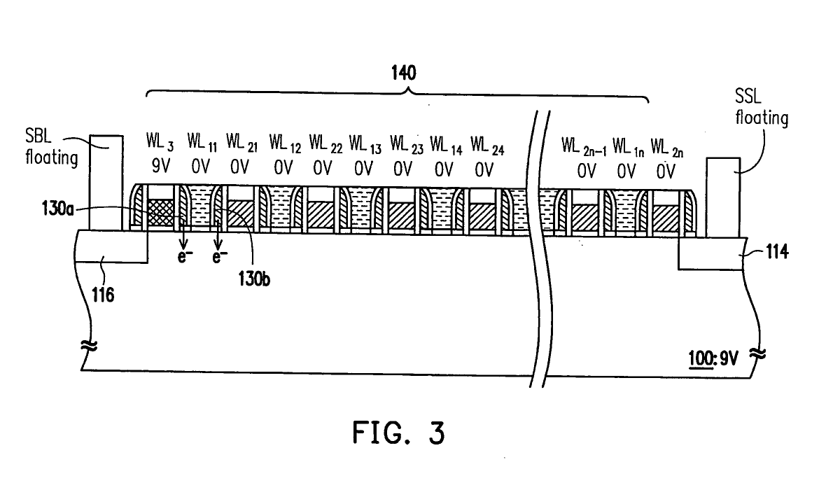

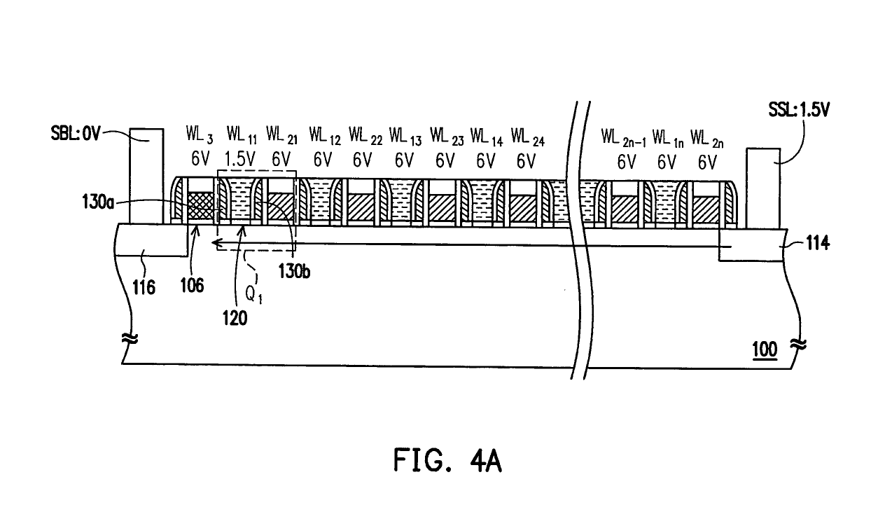

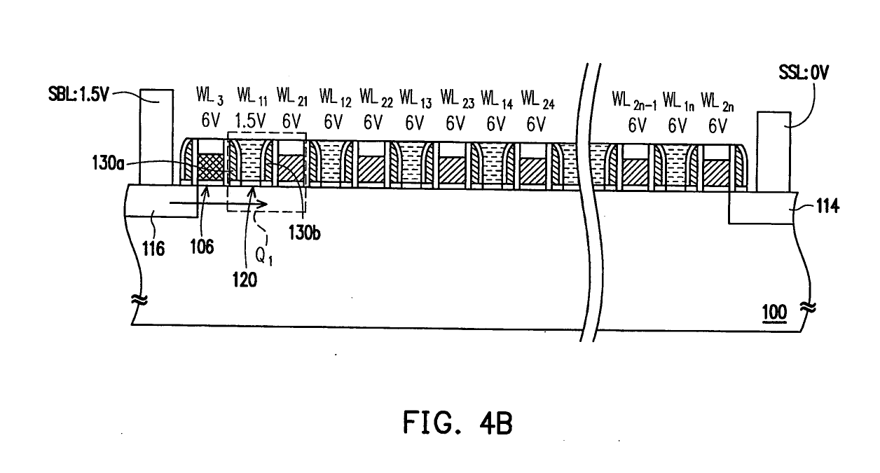

In the following, a method of operating the aforementioned non-volatile memory is described. FIG. 2A is a schematic cross-sectional view for showing the programming of a non-volatile memory according to one embodiment of the present invention. FIG. 2B is a schematic cross-sectional view for showing the programming of data into a non-volatile memory according to another embodiment of the present invention. FIG. 3 is a schematic cross-sectional view for showing the erasing of data from a non-volatile memory according to one embodiment of the present invention. FIG. 4A is a schematic cross-sectional view for showing the reading of data from a non-volatile memory according to one embodiment of the present invention. FIG. 4B is a schematic cross-sectional view for showing the reading of data from a non-volatile memory according to another embodiment of the present invention.

To program, for example, a first bit into the memory cell 120 of the memory unit Q1 as shown in FIG. 2A, a 0V is applied to the selected bit line SBL, a first voltage such as 1.5V is applied to the selected third word line WL3 (the switching unit), a second voltage such as 9V is applied to the non-selected first word lines WL11˜WL1n and the second word lines WL21˜WL2n and a third voltage such as 4.5V is applied to the selected source line SSL so that source-side injection (SSI) is triggered to program data into the selected memory cell, for example, the memory cell 120 of the memory unit Q1 so that the first bit is transferred into the floating gate 130a close to the drain region 116 of the selected memory cell. In particular, the voltage applied to the first word line WL11 of the selected memory cell will couple with the floating gate 130a and generate a coupling voltage on the floating gate 130a. The coupling voltage is about 50%˜60% of the voltage applied to the first word line WL11, which is about 5V, for example.

To program, for example, a second bit into the memory cell 120 of the memory unit Q1 as shown in FIG. 2B, a 0V is applied to the selected bit line SBL, the first voltage such as 1.5V is applied to the first word line WL11 that couples with the selected memory cell 120, the second voltage such as 9V is applied to the non-selected first word lines WL12˜WL1n and the second word lines WL21˜WL2n and the third voltage such as 4.5V is applied to the selected source line SSL so that source-side injection (SSI) is triggered to program data into the selected memory cell, for example, the memory cell 120 of the memory unit Q1 so that the second bit is transferred into the floating gate 130b close to the source region 114 of the selected memory cell. In particular, the voltage applied to the second word lines WL21 and WL22 of the selected memory cell will couple with the floating gate 130a and the floating gate 130b respectively and generate a coupling voltage in the floating gate 130a and the floating gate 130b. The coupling voltage is about 50%˜60% of the voltage applied to the second word lines WL21 and WL22, which is about 5V, for example.

In the operating method of the present invention, when data need to be stored in a selected memory cell, for example, the floating gate 130a close to the drain region 116 of the memory cell 120 in the memory unit Q1, the select unit 118 adjacent to the selected memory cell 120 and close to the drain region 116 serves as a select transistor. Through the lowering of the voltage applied to the select transistor, electrons are injected into the floating gate 130a close to the drain region 116 of the selected memory cell. On the other hand, when data need to be stored in same selected memory cell, for example, the floating gate 130b close to the source region 114 of the memory cell 120 in the memory unit Q1, the control gate 132 of the selected memory cell 120 and the gate dielectric layer 138 underneath can be regarded as another select transistor. Through the lowering of the applied voltage to this select transistor, electrons are injected into the floating gate 130b close to the source region 114 of the selected memory cell. Thus, to program an entire row of memory cells, the aforementioned operating mode can be used to store data into the two floating gates of each memory cell sequentially.

It should be noted that electrons are not stored in the conductive spacer 108b on the sidewall of the select unit 118 closest to the source region 114 because no select unit or memory cell is disposed on that side close to the source region 114. In addition, electrons are not stored in the conductive spacer 108a on the sidewall of the switching unit 106 closest to the drain region 116. The switching unit 106 can be regarded as a switching transistor for controlling the opening or closing of the channel region underneath.

To erase data from the non-volatile memory as shown in FIG. 3, the selected bit line SBL and source line SSL are set to a floating state, a fourth voltage such as 9V is applied to the selected third word line WL3 and the substrate 100, and a 0V is applied to the selected first word lines WL11˜WL1n and the second word lines WL21˜WL2n so that a voltage differential is set up between the gate and the substrate. Thus, electrons are pulled from the floating gates 130a, 130b into the substrate 100 through F-N tunneling effect so that all the data stored within the entire memory cell array are erased.

To read a first bit of data as shown in FIG. 4A, a 0V is applied to the selected bit line SBL, a fifth voltage such as 1.5V is applied to the first word line WL11 and the source line SSL that couple with the selected memory cell, for example, the memory cell 120 of the memory unit Q1, and a sixth voltage such as 6V is applied to the non-selected first word lines WL12˜WL1n, the second word lines WL21˜WL2n and the third word line WL3 so that the first bit is read from the floating gate 130a close to the drain region 116 of the selected memory cell 120.

To read a second bit of data as shown in FIG. 4B, a 0V is applied to the selected source line SSL, the fifth voltage such as 1.5V is applied to the first word line WL11 and the bit line SBL that couple with the selected memory cell, for example, the memory cell 120 of the memory unit Q1, and the sixth voltage such as 6V is applied to the non-selected first word lines WL12˜WL1n, the second word lines WL21˜WL2n and the third word line WL3 so that the second bit is read from the floating gate 130b close to the source region 114 of the selected memory cell 120. According to the aforementioned reading operation, a bi-directional reading mode must be applied to read the left and right bit from the same memory cell individually.

The method of operating the non-volatile memory according to the present invention utilizes source-side injection for programming data into the memory and F-N tunneling effect to erase data from the memory cells. Furthermore, a bi-directional read-out scheme is used to read the left and the right data bit from a selected memory cell. Because the electron injection efficiency is raised in the present invention, the memory cell current can be reduced and the operating speed can be increased. As a result, current consumption is minimized and power loss from the entire chip is reduced.

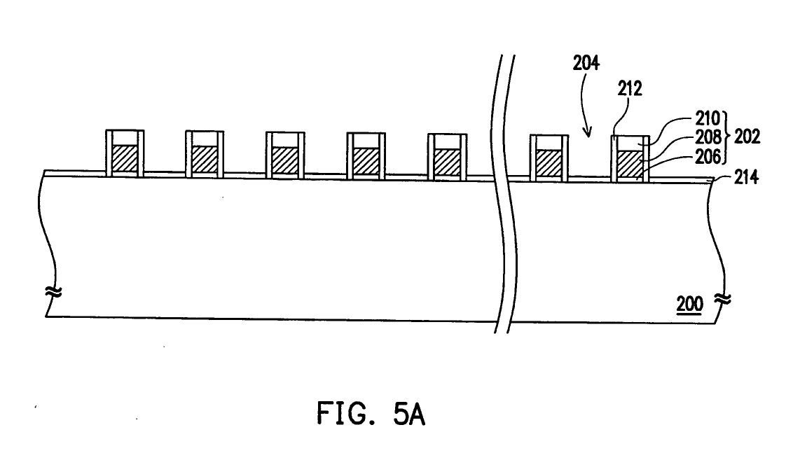

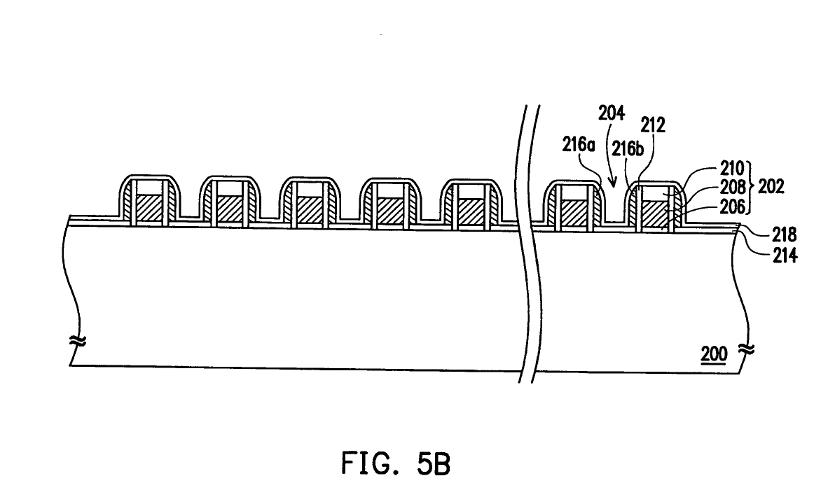

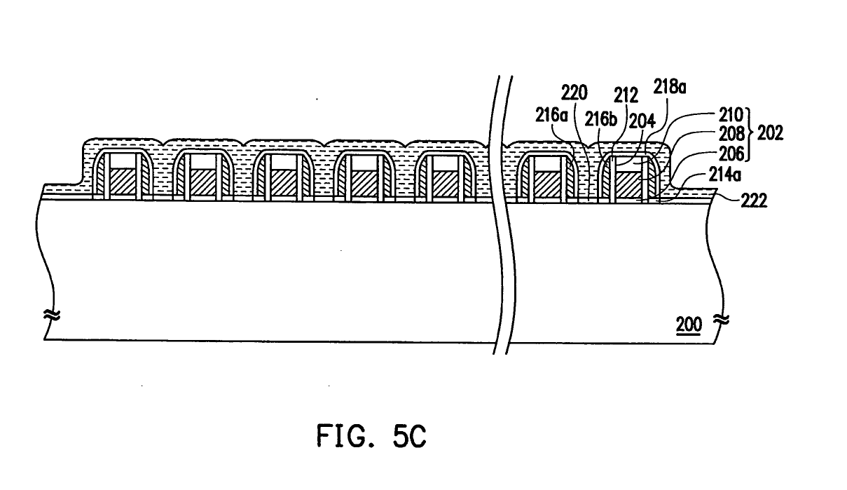

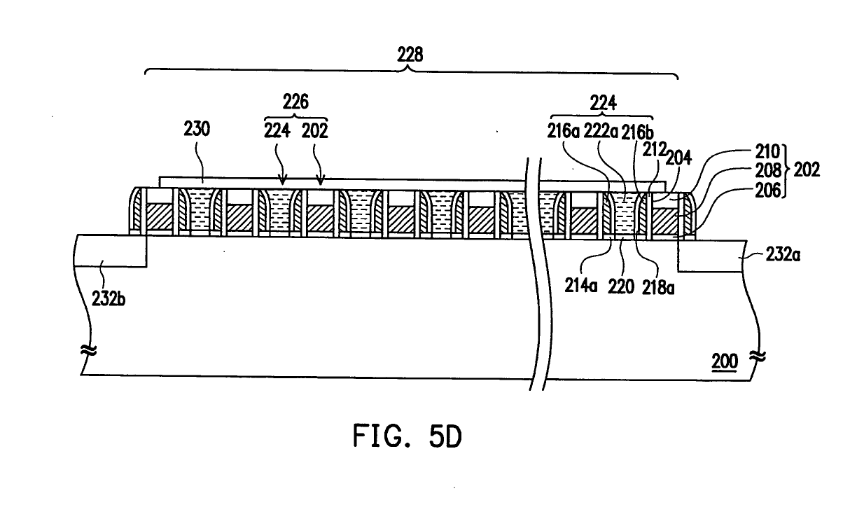

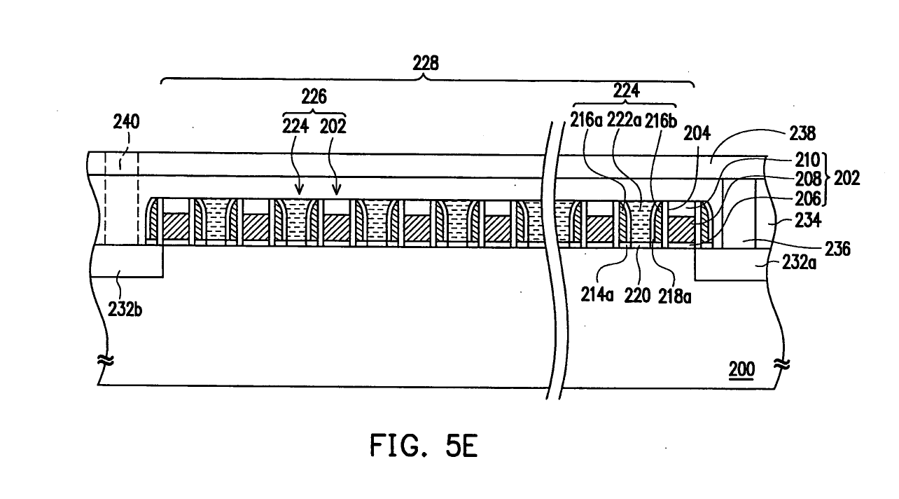

FIGS. 5A through 5E are schematic cross-sectional views along line A-A′ of FIG. 1A showing the steps for fabricating a non-volatile memory according to the present invention. First, as shown in FIG. 5A, a substrate 200 such as a silicon substrate is provided. The substrate 200 has a device isolation structure (not shown) therein. Then, a plurality of stacked gate structures 202 is formed on the substrate 200 such that there is a gap 204 between every pair of adjacent stacked gate structures 202. Each stacked gate structure 202 includes a gate dielectric layer 206, a conductive layer 208 (a gate) and a cap layer 210, for example. The method of fabricating the stacked gate structure 202 includes, for example, forming a gate dielectric material layer, a conductive material layer and an insulating material layer sequentially over the substrate 200 and patterning the aforementioned material layers by performing photolithographic and etching processes thereafter.

The gate dielectric layer 206 is a silicon oxide layer formed, for example, by performing a thermal oxidation process. The conductive layer 208 is a doped polysilicon layer formed, for example, by deposing an undoped polysilicon layer in a chemical vapor deposition and performing an ion implanting process thereafter. The cap layer 210 is a silicon oxide layer formed, for example, by performing a chemical vapor deposition process using tetra-ethyl-ortho-silicate (TEOS)/ozone (O3) as the reactive gases.

Thereafter, a plurality of insulating layers 212 is formed on the sidewalls of the stacked gate structures 202 within the gaps 204 and a tunneling dielectric layer 214 is formed on the surface of the substrate 200. The insulating layers 212 and the tunneling dielectric layer 214 are formed, for example, by performing a conventional oxidation process. Furthermore, the insulating layers 212 and the tunneling dielectric layer 214 is formed in the same oxidation process. Through the oxide layer formed in the oxidation process, the oxide layer on the sidewalls of the stacked gate structures 202 can be used to isolate two conductive layers in a subsequent process and hence serves as an insulating layer. On the other hand, the oxide layer on the surface of the substrate 200 can serve as a tunneling dielectric layer facilitating the tunneling of electric charges.

As shown in FIG. 5B, conductive spacers 261a and 261b are formed on the insulating layer 212 on the respective sidewalls of stacked gate structures 202. The conductive spacers 216a and 216b are fabricated using doped polysilicon, for example. The method of forming the conductive spacers 216a and 216b includes depositing conductive material to form a conductive layer that covers the stacked gate structures 202 and performing a self-aligned anisotropic etching operation to remove a portion of the conductive layer. Specifically, the conductive spacers 216a and 216b within the gap 204 serve as floating gates. Furthermore, because the conductive spacers 216a and 216b are fabricated in the same process and symmetrical to each other, the memory can operate with a higher degree of uniformity.

Thereafter, an inter-gate dielectric layer 218 is formed over the substrate 200 to cover at least the conductive spacers 216a, 216b and the tunneling dielectric layer 214. The inter-gate dielectric layer 218 is a silicon oxide layer or an oxide/nitride/oxide composite dielectric layer, for example.

As shown in FIG. 5C, the gate dielectric layer 218 and the tunneling dielectric layer 214 between two adjacent conductive spacers 216a and 216b are removed to expose a portion of the substrate 200 and form a gate dielectric layer 218a and a tunneling dielectric layer 214a.

Thereafter, a gate dielectric layer 220 is formed over the exposed substrate 200 within the gaps 204. The gate dielectric layer 220 is a silicon oxide layer formed, for example, by performing an oxidation process.

Then, a conductive layer 222 is formed over the substrate 200. The conductive layer 222 fills at least the gap 204 between two adjacent stacked gate structures 202. The conductive layer 222 is a doped polysilicon layer formed, for example, by depositing undoped polysilicon material to form an undoped polysilicon layer and performing an ion implanting process thereafter.

As shown in FIG. 5D, a portion of the conductive layer 222 is removed until the cap layer 210 is exposed so that a plurality of gates 222a is formed between two adjacent stacked gate structures 202. The gates 222a serve control gates. In addition, the gates 222a may be regarded as conductive lines. The gates 222a together with the stacked gate structures 202 form a memory cell row 228. The method of removing a portion of the conductive layer 222 includes performing an etching back process or a chemical mechanical polishing process. In the memory cell row 228, the (control) gate 222a, the gate dielectric layer 220, the conductive spacers 216a, 216b (the floating gates), the inter-gate dielectric layer 218a and the tunneling dielectric layer 214a together constitute a memory cell 224. Furthermore, each memory cell 224 together with a corresponding stacked gate structure 202 forms a memory unit 226. The memory units 226 are isolated from each other through the insulating layers 212. In other words, the memory cell row 228 includes a series of alternately laid memory cells 224 and stacked gate structures 202. Moreover, in the memory cell row 228, the stacked gate structures 202 in the memory cell row 228 may serve as select transistors in subsequent memory operations. Hence, the stacked gate structures 202 can be regarded as select units. In addition, the outermost stacked gate structure 202 in the memory cell row 228 may serve as a switching transistor in subsequent memory operations. As a result, that stacked gate structure 202 can be regarded as a switching unit.

Thereafter, a patterned mask layer 230 that exposes the areas for forming the desired source region and the desired drain region is formed over the substrate 200. An etching process is carried out to remove any residual material of the conductive layer 222 or gate dielectric layer 220 on the areas for forming the source and the drain region.

After that, an ion implantation is carried out using the mask layer 230 as a mask to form a source region 232a and a drain regions 232b in the substrate 200. The source region 232a and the drain region 232b are disposed in the substrate 200 on the respective sides of the memory cell row 228.

As shown in FIG. 5E, the mask layer 230 is removed and then an inter-layer dielectric layer 234 is formed over the substrate 200. The inter-layer dielectric layer 234 is a silicon oxide layer formed, for example, by performing a chemical vapor deposition process. After that, a source line 236 is formed in the inter-layer dielectric layer 234 to connect electrically with the source region 232a. The source line 236 is fabricated using tungsten, for example.

Thereafter, another inter-layer dielectric layer 238 is formed over the substrate 200. The inter-layer dielectric layer 238 is a silicon oxide layer formed, for example, by performing a chemical vapor deposition process. A bit line 240 is formed in the inter-layer dielectric layer 238 to connect electrically with the drain region 232b. The bit line 240 is fabricated using tungsten, for example. Subsequently, other steps for forming a complete non-volatile memory are carried out. Since these steps should be familiar to those skilled in the fabrication of memory, a detailed description is not repeated.

In the method of fabricating a non-volatile memory according to the present invention, various film layers including the floating gates and control gate are filled in the space between adjacent stacked gate structures. Since photolithographic and etching processes are not carried out to form a memory cell between two adjacent stacked gate structures, the production process is simplified and the production cost is reduced.

In the aforementioned embodiment, the fabrication of five memory units is used to illustrate the process. However, this should by no means limit the number of memory units that can be serially connected together. In other words, the method of fabricating a non-volatile memory according to the present invention can be applied to produce a suitable number of serially connected memory units. For example, a total number of between 32 to 64 memory units can be serially connected to form a single memory unit row. In fact, the process of fabricating the non-volatile memory according to the present invention is suitable for producing an entire memory cell array.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of operating a non-volatile memory such as a memory unit array, wherein the memory unit array comprises a plurality of memory units, each memory unit has a select unit and a memory cell and the select unit and the memory cell of each memory unit are alternately laid to form a memory unit row without any gaps in between, furthermore, each memory cell at least includes a pair of separated floating gates, a plurality of switching units disposed to connect with the outermost memory cells of the memory unit rows, a plurality of drain regions disposed in the substrate on the outer side of the respective switching units of the memory unit rows, a plurality of source regions disposed in the substrate on the outer side of the outermost select units of the memory unit rows, a plurality of first word lines aligned in parallel to the column direction for connecting with the control gate of the memory cells in the same column, a plurality of second word lines aligned in parallel to the column direction for connected with the gate of the select units in the same column, a plurality of third word lines for connecting with the gate of the switching units in the same column, a plurality of bit lines aligned in parallel to the row direction and each bit line connected to the respective drain regions of the memory unit row, a plurality of source lines each connected to the source region of the respective memory unit row, the operating method includes:
performing a first bit data programming operation by applying a 0V to the selected bit line, applying a first voltage to the selected third word line, applying a second voltage to the non-selected first word lines, the second word lines and the third word lines, and applying a third voltage to the selected source line so that source-side injection is triggered to program a first bit data into the floating gate close to the drain region of the selected memory cell; and
performing a second bit data programming operation by applying a 0V to the selected bit line, applying the first voltage to the first word line that couples with the selected memory cell, applying the second voltage to the non-selected first word lines, the second word lines and the third word lines, and applying the third voltage to the selected source line so that source-side injection is triggered to program a second bit data into the floating gate close to the source region of the selected memory cell.

2. The operating method of claim 1, wherein the first voltage is about 1.5V, the second voltage is about 9V and the third voltage is about 4.5V.

3. The operating method of claim 1, wherein the method further comprises:
performing an erasing operation by setting the selected bit line and the source line to a floating state, applying a fourth voltage to the selected third word line and the substrate, applying a 0V to the non-selected first word lines, the second word lines and the third word lines so that F-N tunneling is triggered to remove data from the selected.

4. The operating method of claim 3, wherein the fourth voltage is about 9V.

5. The operating method of claim 1, wherein the method further comprises:
performing an operation to read out a first bit of data from the selected memory cell by applying a 0V to the selected bit line, applying a fifth voltage to the first word line that couple with the selected memory cell and the source line and applying a sixth voltage to the non-selected first word lines, second word lines and third word lines so that the first bit of data in the floating gate close to the drain region of the selected memory cell is read out; and
performing an operation to read out a second bit of data from a selected memory cell by applying a 0V to the selected source line, applying the fifth voltage to the first word line that couple with selected memory cell and the bit line and applying the sixth voltage to the non-selected first word lines, second word lines and third word lines so that the second bit of data in the floating gate close to the source region of the selected memory cell is read out.

6. The operating method of claim 5, wherein the fifth voltage is about 1.5V and the sixth voltage is about 6V.
